(19) United States
(12) Patent Application Publication
(10) Pub. No.: US 2026/0245627 A1
(43) Pub. Date: Aug. 20, 2026

(54) MEMORY SYSTEM AND OPERATING METHOD OF THE SAME

(71) Applicant: SK hynix Inc., Icheon-si (KR)

(72) Inventors: Jang Gun KIM, Icheon-si (KR); Gap Sok DO, Icheon-si (KR)

(21) Appl. No.: 19/356,708

(22) Filed: Oct. 13, 2025

(30) Foreign Application Priority Data
Feb. 18, 2025 (KR) 10-2025-0020834

(51) Int. Cl. G11C 16/10; G11C 16/26; G11C 16/30

(52) U.S. Cl. CPC G11C 16/102; G11C 16/26; G11C 16/30

(57) ABSTRACT

An operating method of a memory system includes receiving a first write command and first write data including first reset data and first set data, counting the number of the first reset data, comparing the number of the first reset data with a first threshold; storing the first write data in first memory cells, checking a number of first turned-on memory cells among the first memory cells, by providing a read voltage having a specific voltage level to the first memory cells, calculating a comparison value based on and the number of the first turned-on memory cells, comparing the comparison value with a second threshold to determine whether to perform a sneak handling algorithm operation, and re-storing the write data in the first memory cells.

### CROSS-REFERENCE TO RELATED APPLICATION

This application claims priority under 35 U.S.C. § 119(a) to Korean Patent Application No. 10-2025-0020834, filed in the Korean Intellectual Property Office on Feb. 18, 2025, the entire contents of which are incorporated herein by reference.

### BACKGROUND

### 1. Technical Field

Embodiments relate to an integrated circuit technology and, more particularly, to a memory system and an operating method of the same.

### 2. Related Art

Recently, as an electronic device is reduced in size, has lower power consumption and higher performance, and is diversified, memory capable of storing information is required for various electronic devices, such as computers and portable communication devices. Furthermore, research on memory having various characteristics continues to be conducted.

Memory that is being researched also includes memory capable of storing data by using a characteristic in which the memory switches between different resistance states depending on a voltage or current thereto. Such memory includes resistive random access memory (RRAM), phase change random access memory (PRAM), ferroelectric random access memory (FRAM), magnetic random access memory (MRAM), an E-fuse, and selector only memory (SOM).

### SUMMARY

In an embodiment, an operating method of a memory system may include receiving a first write command and first write data, the first write data including first reset data and first set data, counting a number of the first reset data, comparing the number of the first reset data with a first threshold, storing the first write data in first memory cells, checking a number of first turned-on memory cells among the first memory cells, by providing a read voltage having a specific voltage level to the first memory cells, calculating a first comparison value based on the number of the first turned-on memory cells, comparing the first comparison value with a second threshold to determine whether to perform a sneak handling algorithm operation, and re-storing the first write data in the first memory cells.

In an embodiment, an operating method of a memory system may include receiving a first write command and first write data, the first write data including first reset data and first set data, counting a number of the first reset data, comparing the number of the first reset data with a first threshold, storing the first write data in first memory cells, and updating a proportion of reset data to set data based on a first proportion of the first reset data to the first set data, the proportion having been accumulated and stored before the first write data is received.

In an embodiment, a memory system may include a memory device comprising a plurality of memory cells, a controller configured to receive a write command and write data including reset data and set data, configured to count a number of the reset data, and configured to transmit the write command and the write data to the memory device, and a buffer memory configured to store the write data under a control of the controller and configured to transmit the stored write data to the controller.

### BRIEF DESCRIPTION OF THE DRAWINGS

FIG. 1 is a diagram for describing a memory cell of a memory device according to an embodiment of the present disclosure.

FIGS. 2 and 3 are diagrams for describing write operations of the memory device according to an embodiment of the present disclosure.

FIG. 4 is a diagram for describing a read operation of the memory device according to an embodiment of the present disclosure.

FIGS. 5 and 6 are diagrams for describing a sneak current of a memory device according to an embodiment of the present disclosure.

FIG. 7 is a flowchart of an operating method of a memory system according to an embodiment of the present disclosure.

FIG. 8 is a diagram for describing a set voltage read operation described with reference to FIG. 7.

FIGS. 9, 10A, and 10B are diagrams for describing operating methods of a sneak handling algorithm described with reference to FIG. 7.

FIG. 11 is a diagram for describing a memory system according to an embodiment of the present disclosure.

FIG. 12 is a flowchart of an operating method of the memory system according to another embodiment of the present disclosure.

### DETAILED DESCRIPTION

Hereinafter, embodiments according to the technical spirit of the present disclosure are described with reference to the accompanying drawings.

Embodiments of the present disclosure provide a technology for monitoring a sneak current.

It is possible to improve the data storage reliability of a memory cell.

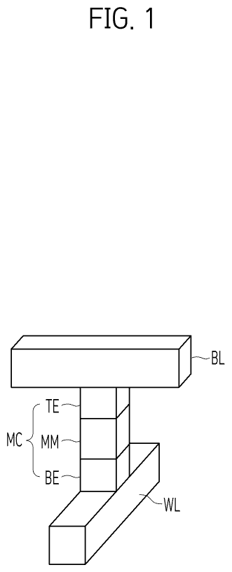

FIG. 1 is a diagram for describing a memory cell of a memory device according to an embodiment of the present disclosure.

Referring to FIG. 1, a memory cell MC of a memory device according to an embodiment of the present disclosure may be disposed between a bit line BL and a word line WL. Furthermore, the memory cell MC may be electrically connected to the bit line BL and the word line WL. In this case, FIG. 1 illustrates that the bit line BL is disposed above the word line WL. However, according to an embodiment, the bit line BL may be disposed below the word line WL. Furthermore, the bit line BL and the word line WL may include a conductive material.

The memory cell MC may include a first electrode TE, a memory material MM, and a second electrode BE. The memory material MM may be disposed between the first electrode TE and the second electrode BE. In this case, the first and second electrodes TE and BE may each include a conductive material. The level of the threshold voltage of the memory material MM may be changed depending on the direction of a current that flows through the memory material MM. The memory material MM may include a chalcogenide-series material.

For example, the second electrode BE may be formed on the word line WL. The memory material MM may be formed on the second electrode BE. The first electrode TE may be formed on the memory material MM. The bit line BL may be formed on the first electrode TE. In this case, the first electrode TE disposed higher than the second electrode BE may be named an upper electrode TE depending on the location at which the first electrode TE is formed. The second electrode BE disposed lower than the first electrode TE may be named a lower electrode BE depending on the location at which the second electrode BE is formed.

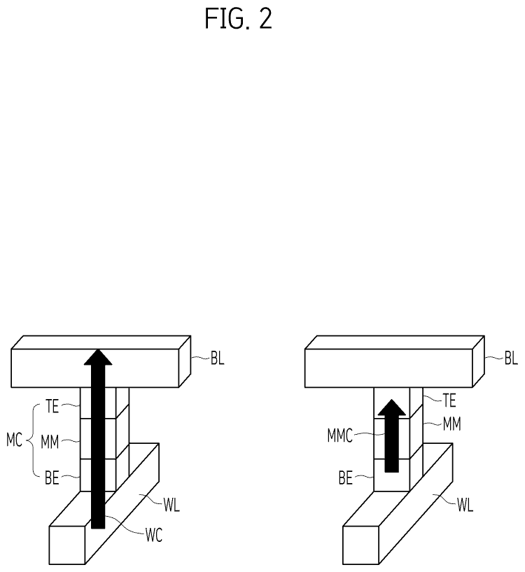

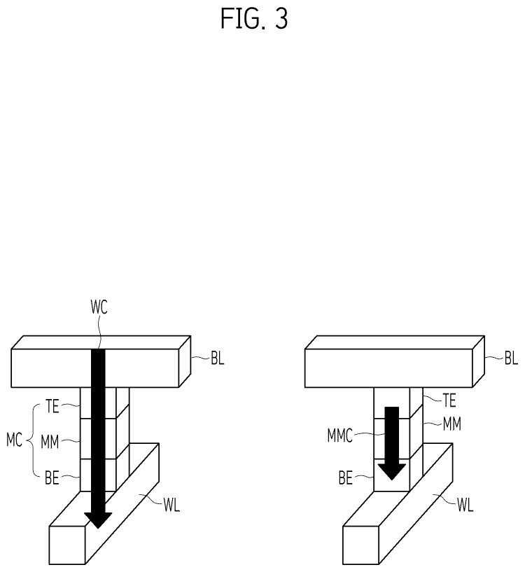

FIGS. 2 and 3 are diagrams for describing write operations of the memory device according to an embodiment of the present disclosure.

FIG. 2 may be a diagram illustrating a write operation when a write current WC flows from the word line WL to the bit line BL through the memory cell MC. The write operation may be an operation of providing the word line WL and the bit line BL with a voltage in which a difference between the voltage levels of the word line WL and the bit line BL is greater than the level of a voltage at which the memory cell MC may be turned on. In this case, a voltage higher than the voltage of the bit line BL may be provided to the word line WL.

Such a write operation may be an operation of changing a memory material characteristic MMC that allows a current to flow more easily through the memory material MM in a first direction than in a second direction. In this case, the first direction may be a direction in which the current flows from the word line WL to the bit line BL through the memory material MM. The second direction may be a direction in which a current flows from the bit line BL to the word line WL through the memory material MM.

FIG. 3 may be a diagram illustrating a write operation when the write current WC flows from the bit line BL to the word line WL through the memory cell MC. The write operation may be an operation of providing the bit line BL and the word line WL with a voltage in which a difference between the voltage levels of the bit line BL and the word line WL is greater than the level of a voltage at which the memory cell MC may be turned on. In this case, a voltage higher than the voltage of the word line WL may be provided to the bit line BL.

Such a write operation may be an operation of changing the memory material characteristic MMC that allows a current to flow more easily through the memory material MM in the second direction than in the second direction. In this case, the first direction may be a direction in which the current flows from the word line WL to the bit line BL through the memory material MM. The second direction may be a direction in which a current flows from the bit line BL to the word line WL through the memory material MM.

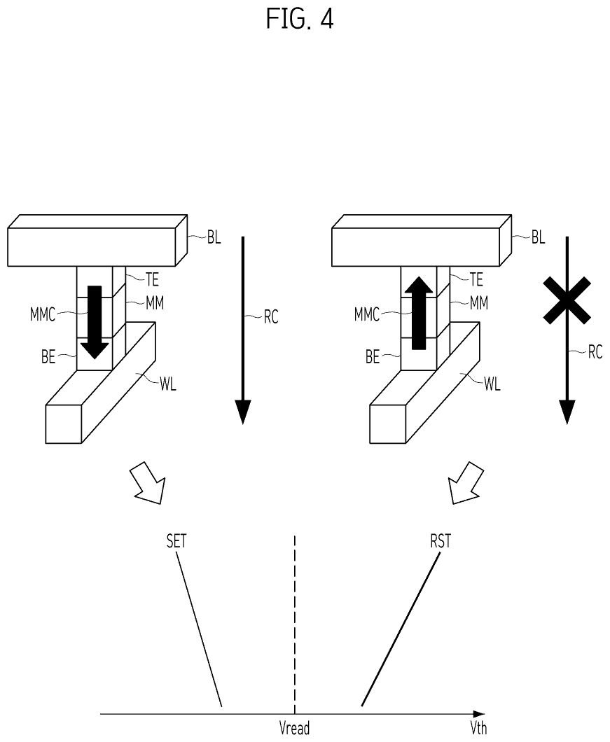

FIG. 4 is a diagram for describing a read operation of the memory device according to an embodiment of the present disclosure.

Referring to FIG. 4, the read operation may be an operation of identifying the state of the memory cell MC by providing the bit line BL with a voltage having a higher level than the voltage of the word line WL. In this case, the read operation may be an operation of making a read current RC flow in the same direction as that of the write current WC after the start of the write operation illustrated in FIG. 3. Furthermore, a difference between the voltage levels of the bit line BL and the word line WL after the start of the read operation may correspond to the level of a read voltage Vread. The read voltage Vread may have a voltage level between the level of the threshold voltage of the memory cell MC according to the write operation illustrated in FIG. 2 and the level of the threshold voltage of the memory cell MC according to the write operation illustrated in FIG. 3.

Accordingly, if the read operation illustrated in FIG. 4 is performed on the memory cell MC having the memory material characteristic MMC changed through the write operation of making the write current WC flow from the bit line BL to the word line WL as illustrated in FIG. 3, the read current RC may flow from the bit line BL to the word line WL through the memory cell MC that has been turned on. At this time, the memory cell MC may be turned on because the level of the threshold voltage of the memory cell MC having the memory material characteristic MMC changed by the write operation illustrated in FIG. 3 may be lower than the level of the read voltage Vread.

If a read operation is performed on the memory cell MC having the memory material characteristic MMC changed through the write operation illustrated in FIG. 2 as illustrated in FIG. 4, the read current FRC might not flow. At this time, the memory cell MC might not be turned on because the level of the threshold voltage of the memory cell MC having the memory material characteristic MMC changed through the write operation illustrated in FIG. 2 is higher than the level of the read voltage Vread. Accordingly, the read current RC might not flow.

The memory cell MC having a threshold voltage that has a lower level than the read voltage Vread may be said to be in a set state SET. The memory cell MC having a threshold voltage that has a higher level than the read voltage Vread may be said to be in a reset state RESET (or RST).

That is, the state of the memory cell MC may be (e.g., changed into) in the set state SET through the write operation illustrated in FIG. 3. Furthermore, the state of the memory cell MC may be (e.g., changed into) in the reset state RESET through the write operation illustrated in FIG. 2. In this case, a write operation of changing the state of the memory cell MC into the set state SET may be named a set write operation. A write operation of changing the state of the memory cell MC into the reset state RESET may be named a reset write operation.

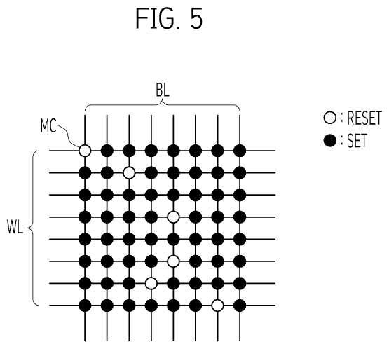

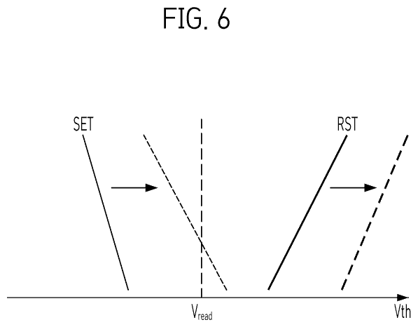

FIGS. 5 and 6 are diagrams for describing a sneak current of a memory device according to an embodiment of the present disclosure.

FIG. 5 may illustrate a memory array including a plurality of memory cells MC that is connected between a plurality of word lines WL and a plurality of bit lines BL. In this case, the memory device may include the memory array including the plurality of memory cells MC.

The state of each of the plurality of memory cells MC may be changed into the set state SET or the reset state RESET through a set write operation or a reset write operation. As described above, the level of the threshold voltage of the memory cell MC in the set state SET may be lower than the level of the threshold voltage of the memory cell MC in the reset state RESET.

Accordingly, a relatively large amount of sneak current may flow through the memory cell MC in the set state SET, compared to the memory cell MC in the reset state RESET.

As illustrated in FIG. 5, the amount of a sneak current that flows through the memory cell array including the plurality of memory cells MC may be increased as the number of memory cells MC in the set state SET is greater than the number of memory cells MC in the reset state RESET.

FIG. 6 may be a diagram for describing an operation in which an error occurs in a read operation as the amount of a sneak current is increased.

The memory device may perform a read operation of checking whether the memory cell MC has been turned on by detecting the voltage level of the bit line BL or the word line WL.

The memory cell MC may be turned on because the level of the threshold voltage of the memory cell MC in the set state SET is lower than the level of the read voltage Vread. The memory cell MC may be turned off because the level of the threshold voltage of the memory cell MC in the reset state RESET is higher than the level of the read voltage Vread. That is, the memory cell MC might not be turned on because the level of the threshold voltage of the memory cell MC in the reset state RESET is higher than the level of the read voltage Vread. In this case, the level of the read voltage Vread that is provided after the start of a read operation may correspond to a difference between the levels of voltages applied to both ends of the memory cell MC. That is, the level of the read voltage Vread may correspond to a difference between the voltage levels of the bit line BL and the word line WL.

For example, the memory device may be configured to compare the level of a reference voltage and the voltage level of a specific node, which rises due to a current that flows through the memory cell MC when the memory cell MC is turned on, in order to determine whether the memory cell MC has been turned on after the start of a read operation.

More specifically, for example, if the memory cell MC is turned on and a current is provided to a specific node when the read voltage Vread is provided to the memory cell MC after the start of a read operation, the voltage level of the specific node may be higher than the level of the reference voltage. At this time, the memory cell MC may be determined to be turned on. If the memory cell MC is not turned on and a current is not provided to a specific node when the read voltage Vread is provided to the memory cell MC after the start of a read operation, the voltage level of the specific node may be lower than the level of the reference voltage. At this time, the memory cell MC may be determined to have not been turned on.

However, as the amount of a sneak current is increased, the voltage level of a specific node might not be higher than the level of a reference voltage although the memory cell MC is turned on after the start of a read operation.

In such a case, the memory cell MC in the set state SET may be determined to have not been turned on and erroneously identified to be in the reset state RESET as illustrated in FIG. 6.

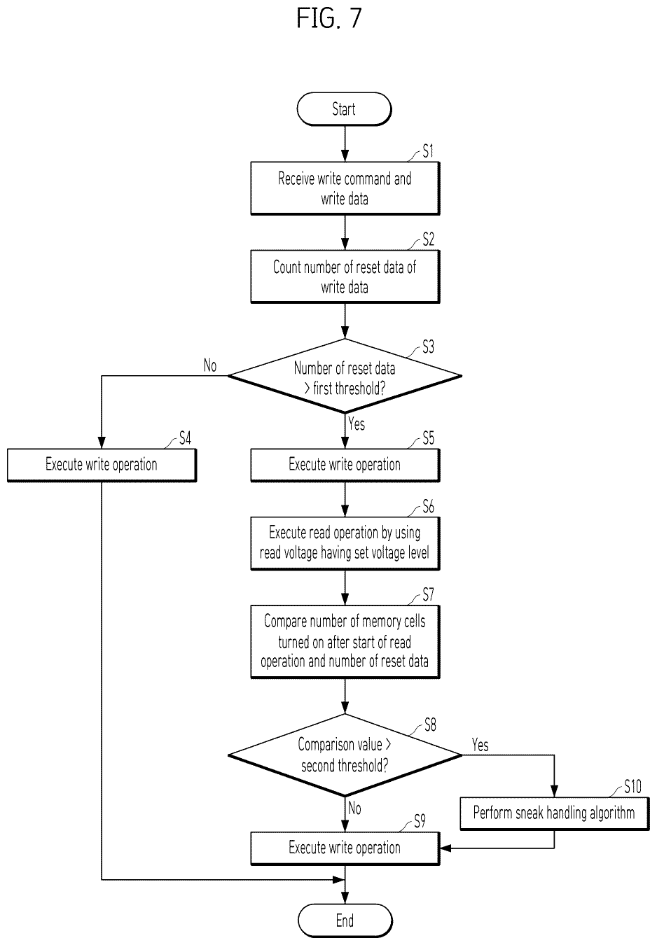

FIG. 7 is a flowchart of an operating method of a memory system according to an embodiment of the present disclosure.

Referring to FIG. 7, the operating method of the memory system according to an embodiment of the present disclosure may include a write command and write data reception process S1, a reset data number count process S2, a first check process S3, a first write operation execution process S4, a second write operation execution process S5, a set voltage read operation execution process S6, a count value comparison process S7, a second check process S8, a third write operation execution process S9, and a sneak handling algorithm execution process S10.

The write command and write data reception process S1 may include a process of receiving, by a memory device, a write command and write data. For example, the write data may include reset data and set data. In this case, the write command may be a command that instructs the memory device to store the write data. The write data may be data to be stored in the memory device. For example, the write command and write data reception process S1 may include a process of transmitting the write command and the write data from a host to a controller.

The reset data number count process S2 may be a process of counting the number of reset data included in the write data. For example, the reset data number count process S2 may include a process of counting the number of reset data, among the write data received by the controller from the host.

The first check process S3 may include a process of comparing the number of reset data counted with a first threshold.

In the embodiment of FIG. 7, when the number of counted reset data is equal to or smaller than the first threshold (No) in the first check process S3, the first write operation execution process S4 may be performed. However, embodiments of the present disclosure are not limited thereto. Specifically, in some embodiments, the method proceeds to S4 when the number of counted reset data is smaller than the first threshold (No) in the first check process S3.

The first write operation execution process S4 may include a process of storing, by the memory device that has received the write command, the write data by transmitting the write command and the write data to the memory device. For example, when the number of data counted by the controller is equal to or smaller than the first threshold (No), the first write operation execution process S4 may include a process of transmitting, by the controller, the write command and the write data received from the host to the memory device and a process of storing, by the memory device, the write data in response to the received write command.

In the embodiment of FIG. 7, when the number of counted reset data is greater than the first threshold (Yes) in the first check process S3, the second write operation execution process S5 may be performed. However, embodiments of the present disclosure are not limited thereto. Specifically, in some embodiments, the method may proceed to S5 when the number of counted reset data is equal to or greater than the first threshold (Yes) in the first check process S3.

The second write operation execution process S5 may include a process of transmitting, by the controller, the write command and the write data to the memory device and storing, by the memory device that has received the write command, the write data.

The set voltage read operation execution process (or a read operation execution process with a specific voltage) S6 may be a process that is performed after the second write operation execution process S5 has been performed, when the number of counted reset data is greater than the first threshold (Yes) in the first check process S3.

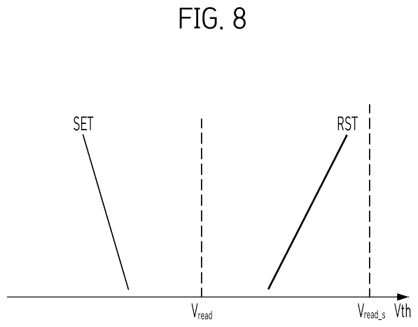

The set voltage read operation execution process S6 may include a process of reading the write data stored in the second write operation execution process S5 by using a read voltage having a specific (e.g., set) voltage level. For example, the set voltage read operation execution process S6 may include a process of providing the read voltage having the set voltage level to memory cells in which the write data have been stored in the second write operation execution process S5 and checking whether the memory cells have been turned on. In this case, in order to check whether the memory cells have been turned on in the set voltage read operation execution process S6, the read voltage having the set voltage level, which is provided to the memory cells, may be higher than the level of a common read voltage (e.g., Vread in FIG. 8). For example, the level of the common read voltage may be higher than the level of the threshold voltage of a memory cell in the set state SET and may be lower than the level of the threshold voltage of a memory cell in the reset state RESET. In this case, the read voltage having the set voltage level may have a higher level than the threshold voltage of the memory cell in the reset state RESET.

The count value comparison process S7 may include a process of comparing the number of memory cells turned on in the set voltage read operation execution process S6 and the number of reset data counted in the reset data number count process S2. In some embodiments, the count value comparison process S7 may include a process of calculating a comparison value based on the number of turned-on memory cells, or the number of counted reset data, or both. For example, the count value comparison process S7 may include a process of calculating a difference between the number of counted reset data and the number of turned-on memory cells as a comparison value.

The second check process S8 may include a process of comparing the comparison value calculated in the count value comparison process S7 with a second threshold to determine whether to perform a sneak handling algorithm operation at S10.

In the embodiment of FIG. 7, when the comparison value calculated in the second check process S8 is equal to or smaller than the second threshold (No), the third write operation execution process S9 may be performed. However, embodiments of the present disclosure are not limited thereto. Specifically, in some embodiments, the method may proceed to S9 when the comparison value calculated in the second check process S8 is smaller than the second threshold (No).

The third write operation execution process S9 may include a process of transmitting, by the controller, the write command and the write data to the memory device and storing, by the memory device that has received the write command, the write data. The reason why the third write operation execution process S9 is performed may be to perform an operation of storing the reset data in the memory cells again because the state of the memory cell in the reset state RESET may be changed into the set state SET in the set voltage read operation execution process S6.

In the embodiment of FIG. 7, when the comparison value calculated in the second check process S8 is greater than the second threshold (Yes), the sneak handling algorithm execution process S10 may be performed. However, embodiments of the present disclosure are not limited thereto. Specifically, in some embodiments, the method proceeds to S10 when the comparison value calculated in the second check process S8 is equal to or greater than the second threshold (Yes).

When the comparison value calculated in the second check process S8 is greater than the second threshold (Yes), the sneak handling algorithm execution process S10 may include a process of checking that the amount of a sneak current is greater than a set amount and performing an algorithm for reducing the amount of the sneak current.

FIG. 8 is a diagram for describing a set voltage read operation described with reference to FIG. 7.

FIG. 8 may illustrate a read voltage Vread_s having a specific voltage level, which is provided to memory cells, in order to check the state of the memory cells in the set read operation execution process S6.

The read voltage Vread that is provided to the memory cell after the start of a common read operation may have a voltage level between the level of the threshold voltage of a memory cell in the set state SET and the level of the threshold voltage of a memory cell in the reset state RESET.

However, the set read operation execution process S6 may include a process of checking whether the memory cell has been turned on by providing the memory cell with the read voltage Vread_s having a higher level than the threshold voltage of the memory cell in the reset state RESET. For example, the read voltage Vread_s may have a specific level higher than a maximum threshold voltage of a memory cell in the reset state RESET when substantially no sneak current flows through the memory cells whose threshold voltages are shown in FIG. 8.

The operating method of the memory system according to an embodiment of the present disclosure may be terminated after counting the number of reset data, among the write data to be stored in the memory device and storing the write data in the memory device when the number of counted reset data is equal to or smaller than the first threshold.

However, in the operating method of the memory system according to an embodiment of the present disclosure, when the number of reset data, among the write data to be stored in the memory device, is greater than the first threshold, the set voltage read operation may be performed after the write data are stored in the memory device. The set voltage read operation may be an operation of checking whether a memory cell in the reset state RESET has been turned on by providing the memory cell with a read voltage having a higher level than the threshold voltage of the memory cell. Accordingly, in the set voltage read operation, all of memory cells in the set state SET and memory cells in the reset state RESET need to be checked as having been turned on. However, all of the memory cells in the set state SET and the memory cells in the reset state RESET might not be checked as having been turned on due to a sneak current. In particular, the number of memory cells checked to have been turned on may be decreased as an amount of the sneak current is increased.

As a result, in the case of the state in which the amount of a sneak current is relatively small, the number of memory cells turned on after the start of a set voltage read operation may be greater than the number of counted reset data.

However, in the case of the state in which the amount of a sneak current is relatively large, the number of memory cells turned on after the start of a set voltage read operation may be smaller than the number of counted reset data.

Accordingly, in the operating method of the memory system according to an embodiment of the present disclosure, when a difference between the number of memory cells turned on after the start of a set voltage read operation and the count value of reset data is greater than the second threshold, the amount of the sneak current may be checked to be relatively large. In some embodiments, when a number of memory cells turned-off after the start of a set voltage read operation is greater than a second threshold, the amount of the sneak current may be determined to be relatively large. For example, the number of memory cells turned-off after the start of a set voltage read operation may be obtained by subtracting the number of memory cells turned-on after the start of a set voltage read operation from the total number of memory cells in the set state SET and reset state RST.

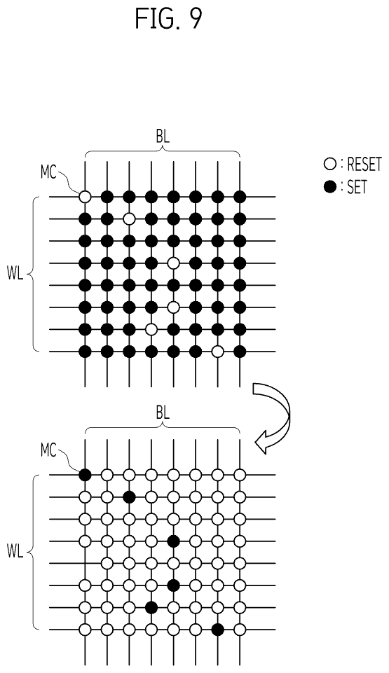

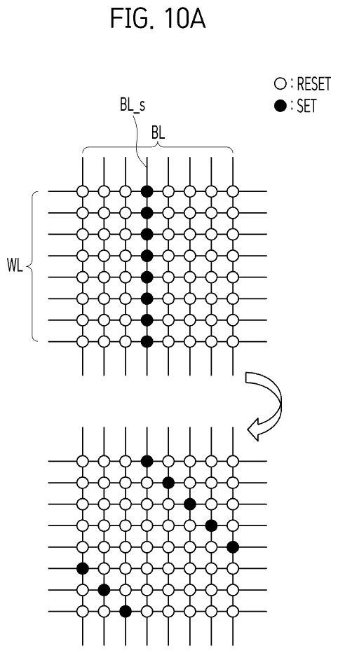

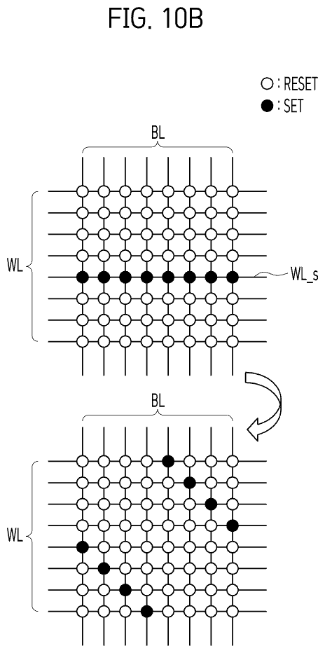

Furthermore, in the operating method of the memory system according to an embodiment of the present disclosure, when the amount of a sneak current is checked to be much, the sneak handling algorithm may be performed. In some embodiments, the sneak handling algorithm may perform inverting data values stored in memory cells as will be described below with reference to FIG. 9, or redistributing specific data values stored in memory cells as will be described below with reference to FIG. 10, or both.

FIGS. 9 and 10 are diagrams for describing operating methods of the sneak handling algorithm described with reference to FIG. 7. In this case, FIGS. 9 and 10 are merely examples of operating methods of the sneak handling algorithm, but embodiments of the present disclosure are not limited thereto.

FIG. 9 may illustrate a memory cell array including a plurality of memory cells.

Referring to FIG. 9, the memory cell array may include a plurality of memory cells that is electrically connected between a plurality of bit lines BL and a plurality of word lines WL. In this case, it is assumed that the number of memory cells in the set state SET is greater than the number of memory cells in the reset state RESET. The amount of a sneak current may be increased as the number of memory cells in the set state SET becomes greater than the number of memory cells in the reset state RESET because the threshold voltages of the memory cells in the set state SET have lower levels than the threshold voltages of the memory cells in the reset state RESET.

In this case, the amount of the sneak current may be reduced by changing the state of the memory cell in the set state SET into the reset state RESET and the state of the memory cell in the reset state RESET into the set state SET so that the number of memory cells in the reset state RESET is greater than the number of memory cells in the set state SET.

As a result, the operating method of the sneak handling algorithm to be described with reference to FIG. 9 may be related to an operating method of an algorithm of storing data values stored in memory cells by inverting the data values when the number of memory cells in the set state SET is greater than the number of memory cells in the reset state RESET.

FIGS. 10A and 10B may illustrate a case in which the number of memory cells in the set state SET is greater than the number of memory cells in the reset state RESET in a specific line of a memory cell array.

Referring to FIG. 10A, the memory cell array may include a plurality of memory cells that is electrically connected between a plurality of bit lines BL and a plurality of word lines WL. In this case, it is assumed that the number of memory cells in the set state SET in a specific bit line BL_s is greater than the number of memory cells in the reset state RESET in other bit lines BL. The amount of a sneak current that flows out from the specific bit line BL_s may be greater than the amount of a sneak current that flows out from other bit lines BL because the threshold voltages of the memory cells in the set state SET have lower levels than the threshold voltages of the memory cells in the reset state RESET.

In this case, the amount of the sneak current may be reduced by redistributing data stored in the memory cells of the specific bit line BL_s to memory cells of other bit lines BL.

Referring to FIG. 10B, a memory cell array may include a plurality of memory cells that is electrically connected between a plurality of bit lines BL and a plurality of word lines WL. In this case, it is assumed that the number of memory cells in the set state SET in a specific word line WL_s is greater than the number of memory cells in the reset state RESET in other word lines WL. The amount of a sneak current that flows out from the specific word line WL_s may be greater than the amount of a sneak current that flows out from other word lines WL because the threshold voltages of the memory cells in the set state SET have lower levels than the threshold voltages of the memory cells in the reset state RESET.

In this case, the amount of the sneak current may be reduced by redistributing data stored in the memory cells of the specific word line WL_s to memory cells of other word lines WL.

As a result, the operating methods of the sneak handling algorithm described above with reference to FIGS. 10A and 10B may be related to an operating method of an algorithm storing data stored in the memory cells of a specific bit line or a specific word line by redistributing the data when the number of memory cells in the set state SET in the specific bit line or the specific word line is greater than the number of memory cells in another bit line or word line.

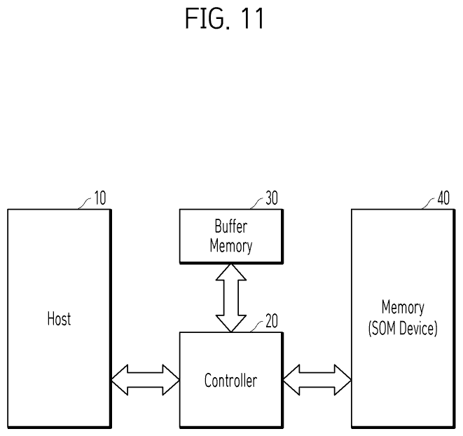

FIG. 11 is a diagram for describing a memory system according to an embodiment of the present disclosure.

Referring to FIG. 11, the memory system according to an embodiment of the present disclosure may include a host 10, a controller 20, a buffer memory 30, and a memory device 40. In some embodiments, the memory device 40 may include a memory cell array including selector only memory (SOM).

The controller 20 may receive a command and data from the host 10. Furthermore, the controller 20 may transmit data stored in the memory device 40 or the buffer memory 30 to the host 10.

The controller 20 may store the data in the buffer memory 30. Furthermore, the controller 20 may receive data stored in the buffer memory 30.

The controller 20 may transmit the command and the data received from the host 10 to the memory device 40. When the command is a write command, the controller 20 may transmit a write command and data to the memory device 40. In this case, the data received from the host 10 are the data to be written in the memory device 40 and thus, it may be named write data. When the command received from the host 10 is a read command, the controller 20 may transmit a read command to the memory device 40, and may transmit data output from the memory device 40 to the host 10.

An operation of the memory system according to an embodiment of the present disclosure is described as follows. In this case, the operating method of the memory system is described by taking an operating method of the memory system described with reference to FIG. 7 as an example.

The controller 20 may receive a write command and write data from the host 10. For example, the write data may include reset data and set data.

The controller 20 may count the number of the reset data in the write data.

When the number of reset data counted by the controller 20 is equal to or smaller than a first threshold, the controller 20 may transmit the write command and write data received from the host 10 to the memory device 40. Thereafter, the memory device 40 may perform a write operation of storing the write data. In this case, the operating method of the memory system according to an embodiment of the present disclosure may be terminated after performing the write operation on the memory device 40 when the number of counted reset data is equal to or smaller than the first threshold.

When the number of counted reset data is greater than the first threshold, the controller 20 may store the write data and an address at which the write data will be stored in the buffer memory 30 and then transmit the write command and the write data to the memory device 40. The memory device 40 that has received the write command and the write data may store the write data. Thereafter, the controller 20 may receive, from the buffer memory 30, the write data and address stored in the buffer memory 30. The controller 20 may perform a set voltage read operation (or a read operation with a specific voltage) on the memory device 40 based on the address received from the buffer memory 30. That is, the controller 20 may perform a read operation of providing a read voltage having a specific (e.g., set) voltage level to memory cells at locations at which the write data have been stored. In this case, the specific voltage level of the read voltage may be higher than the threshold voltage of a memory cell in the reset state RESET.

The controller 20 may compare the results of the read operation received from the memory device 40 and the reset data received from the buffer memory 30. That is, the controller 20 may check the number of turned-on memory cells based on the results of the read operation received from the memory device 40, and may compare the number of turned-on memory cells and the number of reset data.

When the amount of a sneak current is relatively low, the number of turned-on memory cells may be greater than the number of reset data, because the read operation has been performed by using the voltage having a higher level than the threshold voltage of the memory cell in the reset state RESET.

However, the number of turned-on memory cells may be smaller than the number of reset data if the amount of the sneak current is relatively large, although the read operation has been performed by using the voltage having a higher level than the threshold voltage of the memory cell in the reset state RESET.

Accordingly, the controller 20 may monitor the amount of the sneak current based on a comparison result between the number of turned-on memory cells and the number of reset data.

When the controller 20 determines that the amount of the sneak current is relatively low, the controller 20 may control the memory device 40 to store the write data in the address received from the buffer memory 30.

When the controller 20 determines that the amount of the sneak current is relatively high, the controller 20 may perform the sneak handling algorithm on the memory device 40. Thereafter, the controller 20 may control the memory device 40 to store the write data in the address received from the buffer memory 30.

The memory system according to an embodiment of the present disclosure may be configured to determine that the amount of a sneak current is relatively large, when a difference between the number of turned-on memory cells and the number of reset data is greater than a second threshold.

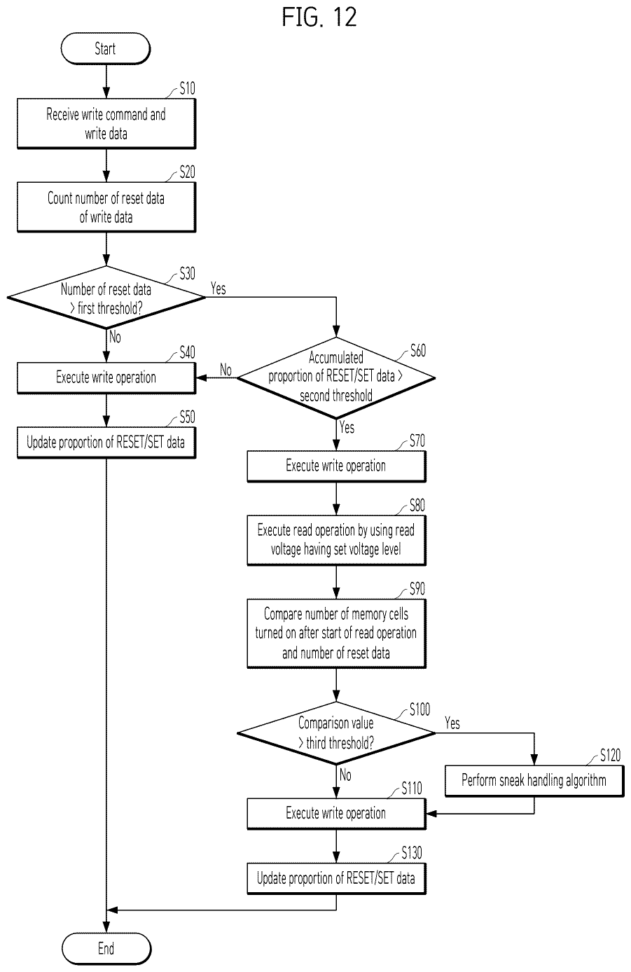

FIG. 12 is a flowchart of an operating method of the memory system according to another embodiment of the present disclosure. For example, a controller (e.g., the controller 20 in FIG. 11) may perform the operating method according to an embodiment of the present disclosure.

Referring to FIG. 12, the operating method of the memory system according to another embodiment of the present disclosure may include a write command and write data reception process S10, a reset data number count process S20, a first check process S30, a first write operation execution process S40, a first proportion update process S50, a second check process S60, a second write operation execution process S70, a set voltage read operation execution process S80, a count value comparison process S90, a third check process S100, a third write operation execution process S110, a sneak handling algorithm execution process S120, and a second proportion update process S130.

The write command and write data reception process S10 may include a process of receiving a write command and write data in a memory device. In this case, the write command may be a command that instructs the memory device to store the write data. The write data may be data to be stored in the memory device. For example, the write command and write data reception process S10 may include a process of transmitting the write command and the write data from the host to the controller.

The reset data number count process S20 may a process of counting the number of reset data included in the write data. For example, the reset data number count process S20 may include a process of counting, by the controller, the number of reset data, among the write data received from the host.

The first check process S30 may include process of comparing the number of counted reset data with a first threshold.

In the embodiment of FIG. 12, when the number of counted reset data is equal to or smaller than the first threshold (No) in the first check process S30, the first write operation execution process S40 may be performed. However, embodiments of the present disclosure are not limited thereto. Specifically, in some embodiments, the method may proceed to the first write operation execution process S40 when the number of counted reset data is smaller than the first threshold (No) in the first check process S30.

The first write operation execution process S40 may include a process of storing, by the memory device that has received the write command, the write data by transmitting the write command and the write data to the memory device. For example, the first write operation execution process S40 may include a process of transmitting, by the controller, the write command and write data received from the host to the memory device and a process of storing, by the memory device, the write data in response to the received write command, when the number of data counted by the controller is equal to or smaller than the first threshold (No).

After the first write operation execution process S40 is performed, the first proportion update process S50 may be performed.

The first proportion update process S50 may include a process of accumulating and storing the proportion of the reset data and set data of the write data. For example, the first proportion update process S50 may include a process of calculating, by the controller, the proportion of the reset data and set data of the write data and storing the proportion of the reset data and the set data in the buffer memory. In some embodiments, the controller may update the accumulated proportion of reset data and set data based on a proportion of the reset data and the set data in the write data received at S10. Specifically, the controller may update the accumulated proportion of the reset data and set data by adding the number of reset data in the write data to the previously accumulated number of reset data, adding the number of set data in the write data to the previously accumulated number of set data, and dividing the added number of reset data by the added number of set data.

When the number of counted reset data is greater than the first threshold (Yes) in the first check process S30, the second check process S60 may be performed.

The second check process S60 may include a process of comparing the proportion of the reset data and set data, which has been accumulated and stored, with a second threshold. For example, the proportion of the reset data and set data that has been accumulated and stored before the write data is received at S10 may be compared with a second threshold. In this case, the proportion of the reset data and the set data, which has been accumulated and stored, may have a higher value as the number of reset data is greater than the number of set data. In other words, a proportion of the reset data to the set data in the write data received at S10 may have a value that increases as the number of the reset data becomes greater than the number of the set data in the write data. For example, the second check process S60 may include a process of comparing, by the controller, the proportion of the reset data and the set data, which has been accumulated and stored in the buffer memory, and the second threshold.

When the proportion of the reset data and the set data, which has been accumulated and stored, is equal to or smaller than the second threshold (No) in the second check process S60, the first write operation execution process S40 and the first proportion update process S50 may be performed.

In the embodiment of FIG. 12, when the proportion of the reset data and the set data, which has been accumulated and stored, is greater than the second threshold (Yes) in the second check process S60, the second write operation execution process S70 may be performed. However, embodiments of the present disclosure are not limited thereto. Specifically, in some embodiments, the method may proceed to the second write operation execution process S70 when the proportion of the reset data and the set data, which has been accumulated and stored, is equal to or greater than the second threshold (Yes) in the second check process S60.

The second write operation execution process S70 may include a process of transmitting, by the controller, the write command and the write data to the memory device and storing, by the memory device that has received the write command, the write data.

After the second write operation execution process 70 is performed, the set voltage read operation execution process (or a read operation execution process with a specific voltage) S80 may be performed.

The set voltage read operation execution process S80 may include a process of reading the write data stored in the second write operation execution process S70, by using a read voltage having a specific (e.g., set) voltage level. For example, the set voltage read operation execution process S80 may include a process of providing the read voltage having the set voltage level to memory cells in which the write data have been stored in the second write operation execution process S70 and checking whether the memory cells have been turned on. In this case, in order to check whether the memory cells have been turned on in the set voltage read operation execution process S70, the read voltage having the set voltage level, which is provided to the memory cells, may have a higher level than a common read voltage. For example, the level of the common read voltage may be higher than the level of the threshold voltage of a memory cell in the set state SET, and may be lower than the level of the threshold voltage of a memory cell in the reset state RESET. In this case, the read voltage having the set voltage level may have a higher level than the threshold voltage of the memory cell in the reset state RESET. More specifically, the set voltage read operation execution process S80 may include a process of reading, by the memory device, the memory cells by using a read voltage having a higher level than the threshold voltage of the memory cell in the reset state RESET under the control of the controller and providing the results of the read to the controller. In this case, the results of the read may include the number of memory cells that have been turned on and the number of memory cells that have not been turned on.

The count value comparison process S90 may include a process of comparing the number of memory cells turned on in the set voltage read operation execution process S80 with the number of reset data counted in the reset data number count process S20. In some embodiments, the count value comparison process S90 may include a process of calculating a comparison value based on the number of counted reset data and the number of turned-on memory cells. For example, the count value comparison process S90 may include a process of calculating a difference between the number of reset data and the number of turned-on memory cells as a comparison value.

The third check process S100 may include a process of comparing a third threshold with the comparison value calculated in the count value comparison process S90 to determine whether to perform a sneak handling algorithm operation at S120.

In the embodiment of FIG. 12, when the comparison value calculated in the third check process S100 is equal to or smaller than the third threshold (No), the third write operation execution process S110 may be performed. However, embodiments of the present disclosure are not limited thereto. Specifically, in some embodiments, the method may proceed to the third write operation execution process S110 when the comparison value calculated in the third check process S100 is smaller than the third threshold (No).

In the embodiment of FIG. 12, when the comparison value calculated in the third check process S100 is greater than the third threshold (Yes), the sneak handling algorithm execution process S120 may be performed. However, embodiments of the present disclosure are not limited thereto. Specifically, in some embodiments, the method may proceed to the sneak handling algorithm execution process S120 when the comparison value calculated in the third check process S100 is equal to or greater than the third threshold (Yes).

The sneak handling algorithm execution process S120 may include a process of checking that the amount of a sneak current is greater than a set amount when the comparison value calculated in the second check process S8 is greater than the second threshold (Yes) and performing an algorithm for reducing the amount of the sneak current.

After the sneak handling algorithm execution process 120 is performed, the third write operation execution process S110 may be performed.

The third write operation execution process S110 may include a process of transmitting, by the controller, a write command and write data to the memory device and storing, by the memory device that has received the write command, the write data. The reason why the third write operation execution process S110 is performed may be to perform an operation of storing the reset data in the memory cells again because the memory cell in the reset state RESET may change into the set state SET in the set voltage read operation execution process S80.

After the third write operation execution process 110 is performed, the second proportion update process S130 may be performed.

The second proportion update process S130 may include a process of accumulating and storing the proportion of the reset data and set data of the write data. For example, the second proportion update process S130 may include a process of storing, by the controller, calculating the proportion of the reset data and set data of the write data and storing the proportion of the reset data and the set data in the buffer memory.

Although some embodiments according to the technical spirit of the present disclosure have been described above with reference to the accompanying drawings, these embodiments have been provided to merely describe embodiments according to the concept of the present disclosure, and various embodiments of the present disclosure are not limited to the above-described embodiments. A person having ordinary knowledge in the art to which the present disclosure pertains may substitute, modify, and change the embodiments in various ways, and such substitutions, modifications, and changes may belong to the scope of embodiments of the present disclosure.

What is claimed is:

1. An operating method of a memory system, comprising:
receiving a first write command and first write data, the first write data including first reset data and first set data;
counting a number of the first reset data;
comparing the number of the first reset data with a first threshold;
storing the first write data in first memory cells;
checking a number of first turned-on memory cells among the first memory cells, by providing a read voltage having a specific voltage level to the first memory cells;
calculating a first comparison value based on the number of the first turned-on memory cells;
comparing the first comparison value with a second threshold to determine whether to perform a sneak handling algorithm operation; and
re-storing the first write data in the first memory cells.

2. The operating method of claim 1, wherein the specific voltage level of the read voltage is higher than a threshold voltage of a memory cell in a reset state.

3. The operating method of claim 1, wherein the calculating of the first comparison value comprises calculating a difference between the number of the first turned-on memory cells and the number of the first reset data as the first comparison value.

4. The operating method of claim 1, further comprising:
receiving a second write command and second write data, the second write data including second reset data and second set data;
counting a number of the second reset data;
comparing the number of the second reset data with the first threshold; and
storing the second write data in second memory cells.

5. The operating method of claim 1, further comprising:
receiving a third write command and third write data, the third write data including third reset data and third set data;
counting a number of the third reset data;
comparing the number of the third reset data with the first threshold;
storing the third write data in third memory cells;
checking a number of second turned-on memory cells among the third memory cells, by providing the read voltage to the third memory cells;
calculating a second comparison value based on the number of the second turned-on memory cells; and
comparing the second comparison value with the second threshold to determine whether to perform the sneak handling algorithm operation on the third memory cells.

6. The operating method of claim 5, wherein the specific voltage level of the read voltage is higher than a threshold voltage of a memory cell in a reset state.

7. The operating method of claim 6, wherein the calculating of the second comparison value comprises calculating a difference between the number of the second turned-on memory cells and the number of the third reset data as the second comparison value.

8. An operating method of a memory system, comprising:
receiving a first write command and first write data, the first write data including first reset data and first set data;
counting a number of the first reset data;
comparing the number of the first reset data with a first threshold;
storing the first write data in first memory cells; and
updating a proportion of reset data to set data based on a first proportion of the first reset data to the first set data, the proportion having been accumulated and stored before the first write data is received.

9. The operating method of claim 8, wherein the first proportion has a value that increases as the number of the first reset data becomes greater than the number of the first set data.

10. The operating method of claim 8, further comprising:
receiving a second write command and second write data, the second write data including second reset data and second set data;
counting a number of the second reset data;
comparing the number of the second reset data with the first threshold;
comparing the updated proportion with a second threshold;
storing the second write data in second memory cells; and
updating the compared proportion based on a second proportion of the second reset data to the second set data.

11. The operating method of claim 8, further comprising:
receiving a third write command and third write data, the third write data including third reset data and third set data;
counting a number of the third reset data;
comparing the number of the third reset with the first threshold;
comparing the updated proportion to a second threshold;
storing the third write data in third memory cells;
comparing a number of first turned-on memory cells, among the third memory cells, by providing a read voltage having a specific voltage level to the third memory cells;
calculating a comparison value based on the number of the first turned-on memory cells;
comparing the comparison value with a third threshold to determine whether to perform a sneak handling algorithm operation;
re-storing the third write data in the third memory cells; and
updating the compared proportion based on a third proportion of the third reset data to the third set data.

12. The operating method of claim 8, further comprising:
receiving a fourth write command and fourth write data, the fourth write data including fourth reset data and fourth set data;
counting a number of the fourth reset data;
comparing the number of the fourth reset data with the first threshold;
comparing the updated proportion with a second threshold;
storing the fourth write data in fourth memory cells;
comparing a number of second turned-on memory cells, among the fourth memory cells, by providing a read voltage having a specific voltage level to the fourth memory cells;
calculating a comparison value based on the number of the second turned-on memory cells;
comparing the comparison value with a third threshold; and
performing a sneak handling algorithm operation on the fourth memory cells, when the comparison value is greater than the third threshold;
re-storing the fourth write data in the fourth memory cells; and
updating the compared proportion based on a third proportion of the fourth reset data to the fourth set data.

13. A memory system comprising:
a memory device comprising a plurality of memory cells;
a controller configured to receive a write command and write data including reset data and set data, configured to count a number of the reset data, and configured to transmit the write command and the write data to the memory device; and
a buffer memory configured to store the write data under a control of the controller and configured to transmit the stored write data to the controller.

14. The memory system of claim 13, wherein the controller stores the write data in the plurality of memory cells by transmitting the write command and the write data to the memory device.

15. The memory system of claim 14, wherein the controller checks a number of turned-on memory cells among the plurality of memory cells, by providing a read voltage having a specific voltage level to the plurality of memory cells.

16. The memory system of claim 15, wherein the specific voltage level of the read voltage is higher than a threshold voltage of a memory cell in a reset state.

17. The memory system of claim 16, wherein the controller compares the counted number of the reset data with the number of the turned-on memory cells.

18. The memory system of claim 17, wherein the controller calculates a comparison value based on the number of the turned-on memory cells and the counted number of the reset data, and determines whether to perform a sneak handling algorithm operation on the memory device by comparing the comparison value with a third threshold.

19. The memory system of claim 18, wherein the sneak handling algorithm operation includes inverting data values stored in the memory cells, or redistributing specific data values stored in the memory cells, or both.

20. The memory system of claim 18, wherein the comparison value is a difference between the number of the turned-on memory cells and the counted number of the reset data,
wherein the controller performs the sneak handling algorithm operation on the memory device when the difference between the number of the turned-on memory cells and the counted number of the reset data is greater than the third threshold, and
wherein the controller stores the write data in the plurality of memory cells when the difference between the number of the turned-on memory cells and the counted number of the reset data is equal to or smaller than the third threshold.

21. The memory system of claim 13, wherein the buffer memory accumulates and stores a proportion, and the controller updates the accumulated and stored proportion based on a first proportion of the reset data to the set data of the write data.

22. The memory system of claim 21, wherein the controller:
stores the write data in the plurality of memory cells when the accumulated and stored proportion is greater than a second threshold; and
causes the memory device to perform a read operation by using a read voltage having a specific voltage level to obtain a number of turned-on memory cells among the plurality of memory cells.

23. The memory system of claim 22, wherein the controller
causes the memory device to perform a sneak handling algorithm operation when a difference between the number of the turned-on memory cells and the number of the reset data is greater than a third threshold.

24. The memory system of claim 23, wherein the sneak handling algorithm operation includes inverting data values stored in the memory cells, or redistributing specific data values stored in the memory cells, or both.

25. The memory system of claim 22, wherein the controller:
stores the write data in the plurality of memory cells when a difference between the number of the turned-on memory cells and the number of the reset data is equal to or smaller than a third threshold.
